(19) United States
(12) Patent Application Publication
(10) Pub. No.: US 2022/0263498 A1
(43) Pub. Date: Aug. 18, 2022

(54) CIRCUIT AND ELECTRONIC DEVICE

(71) Applicant: HUAWEI TECHNOLOGIES CO., LTD., Shenzhen (CN)

(72) Inventor: Zhigang JIN, Shenzhen (CN)

(73) Assignee: HUAWEI TECHNOLOGIES CO., LTD., Shenzhen (CN)

(21) Appl. No.: 17/739,503

(22) Filed: May 9, 2022

Related U.S. Application Data
(63) Continuation of application No. PCT/CN2020/127445, filed on Nov. 9, 2020.

(30) Foreign Application Priority Data
Nov. 14, 2019 (CN) 201911114439.6

(51) Int. Cl. H03K 3/037; H03K 3/012

(52) U.S. Cl. CPC H03K 3/037; G11C 19/00; H03K 3/012

(57) ABSTRACT

A circuit, including a synchronizer register and a level shifter. The synchronizer register is electrically connected to the level shifter, the level shifter is powered by a dual-rail power supply, and a high-voltage power supply in the dual-rail power supply supplies power to the synchronizer register. A metastable state elimination capability of the synchronizer register can be improved by using the circuit.

### CROSS-REFERENCE TO RELATED APPLICATIONS

This application is a continuation of International Application No. PCT/CN2020/127445, filed on Nov. 09, 2020, which claims priority to Chinese Patent Application No. 201911114439.6, filed on Nov. 14, 2019. The disclosures of the aforementioned applications are hereby incorporated by reference in their entireties.

### TECHNICAL FIELD

The embodiments relate to the field of communication technologies, and in particular, to a circuit.

### BACKGROUND

With an increase in a design scale of electronic hardware and emergence of the system on chip (SOC), a quantity of clock domain crossing signal circuits in a design of a field programmable gate array (FPGA) and an application-specific integrated circuit (ASIC) increases correspondingly. As a result, a probability of a metastable state caused by clock domain crossing in the circuit also increases.

The probability of the metastable state may be reduced through sampling performed by a synchronizer register. Currently, a probability of a metastable state that occurs after the synchronizer register performs processing may be described according to a formula

$$MTBF = \frac{{e}^{\frac{t}{C 1}}}{α fC 2} .$$

MTBF represents mean time between failures (MTBF). tin the formula is a maximum valid metastable state resolving time period, and indicates time taken by the synchronizer register to recover from the metastable state. f is a sampling clock frequency, that is, a clock frequency of the register. α is a frequency at which an asynchronous event is triggered, that is, a quantity of asynchronous input changes per second. C1 and C2 are parameters of the register, which are determined by electrical characteristics of the register and can represent a register flip speed. The MTBF can be extended by increasing t or decreasing C1, C2, α, and f, to extend an interval between two failures.

Currently, a common practice in the industry for reduction of a probability of a metastable state is to increase a value oft, that is, to increase a beat quantity of an asynchronous sampling register. However, an increase in the beat quantity of the asynchronous sampling register significantly increases a system delay and greatly affects system performance Therefore, it is significant to improve a metastable state elimination capability of a synchronizer register.

### SUMMARY

Embodiments provide a circuit, to improve a metastable state elimination capability of a synchronizer register.

To achieve the foregoing objective, embodiments provide the following solutions.

A first aspect provides a circuit. The circuit may include a synchronizer register and a level shifter. The synchronizer register is electrically connected to the level shifter, the level shifter is powered by a dual-rail power supply, and a high-voltage power supply in the dual-rail power supply supplies power to the synchronizer register. It can be understood from the first aspect that a power supply voltage of the synchronizer register can be separately increased, to further improve a metastable state elimination capability of the synchronizer register.

Optionally, with reference to the first aspect, in a first possible implementation, the circuit may include one synchronizer register and N level shifters. The synchronizer register includes N ports, each of the N ports is connected to one of the N level shifters, and level shifters connected to any two of the N ports are different, where N is a positive integer.

Optionally, with reference to the first aspect, in a second possible implementation, the circuit includes M synchronizer registers. The M synchronizer registers are connected in a cascading manner, and the high-voltage power supply in the dual-rail power supply supplies power to the M synchronizer registers.

Optionally, with reference to the second possible implementation of the first aspect, in a third possible implementation, a value of M is 2.

A second aspect provides an electronic device. The electronic device includes a circuit. The circuit may include a synchronizer register and a level shifter. The synchronizer register is electrically connected to the level shifter, the level shifter is powered by a dual-rail power supply, and a high-voltage power supply in the dual-rail power supply supplies power to the synchronizer register.

Optionally, with reference to the second aspect, in a first possible implementation, the circuit may include one synchronizer register and N level shifters. The synchronizer register includes N ports, each of the N ports is connected to one of the N level shifters, and level shifters connected to any two of the N ports are different, where N is a positive integer.

Optionally, with reference to the second aspect, in a second possible implementation, the circuit includes M synchronizer registers. The M synchronizer registers are connected in a cascading manner, and the high-voltage power supply in the dual-rail power supply supplies power to the M synchronizer registers.

Optionally, with reference to the second possible implementation of the second aspect, in a third possible implementation, a value of M is 2.

Optionally, with reference to the second aspect, the first possible implementation of the second aspect, or the second possible implementation of the second aspect, in a fourth possible implementation, the electronic device may further include a peripheral logic circuit. A low voltage in the dual-rail power supply supplies power to the peripheral logic circuit. It can be understood from the fourth possible implementation of the second aspect that, when a voltage of the power supply for the peripheral logic circuit is reduced for power consumption reduction, the power supply voltage of the synchronizer register remains unchanged, so that the metastable state elimination capability of the synchronizer register is not affected.

Optionally, with reference to the second aspect, the first possible implementation of the second aspect, or the second possible implementation of the second aspect, in a fifth possible implementation, a dual-rail memory is further included. The dual-rail power supply for the level shifter is the dual-rail power supply for the memory.

The synchronizer register may be powered by a separate power supply, which is different from the power supply for the peripheral logic circuit. Compared with supplying power to a synchronizer register and a peripheral logic circuit by using a same power supply, the solution can further improve the metastable state elimination capability of the synchronizer register. In addition, when a voltage of the power supply for the peripheral logic circuit decreases, the power supply voltage of the synchronizer register remains unchanged, that is, a voltage of a second power supply remains unchanged, so that the metastable state elimination capability of the synchronizer register is not affected.

### BRIEF DESCRIPTION OF DRAWINGS

FIG. 1 is a schematic diagram of a structure of a circuit;

FIG. 2 is a schematic diagram of a structure of another circuit; and

FIG. 3 is a schematic diagram of a structure of an electronic device.

### DETAILED DESCRIPTION OF THE EMBODIMENTS

The embodiments provide a circuit, to improve a metastable state elimination capability of a synchronizer register. The embodiments further provide a corresponding electronic device. Detailed descriptions are provided separately below.

The following clearly describes the solutions in the embodiments with reference to the accompanying drawings in the embodiments. It is clear that the described embodiments are merely some but not all of the embodiments. All other embodiments obtained by a person skilled in the art based on the embodiments without creative efforts shall fall within the scope of the embodiments.

With an increase in a design scale of electronic hardware and emergence of a system on chip (SOC), a quantity of clock domain crossing signal circuits in a design of a field programmable gate array (FPGA) and an application-specific integrated circuit (ASIC) increases correspondingly. As a result, a probability of a metastable state caused by clock domain crossing in the circuit also increases. Clock domain crossing is sometimes referred to as clock domain asynchronization. When a signal is transferred between clock domains, a probability of a metastable state may be reduced by using synchronizer register sampling. Currently, a probability of a metastable state after synchronizer register processing may be described with a following formula:

$$MTBF = \frac{{e}^{\frac{t}{C 1}}}{α fC 2}$$

MTBF represents mean time between failures (MTBF). t in the formula is a maximum valid metastable state resolving time period, and indicates time taken by the synchronizer register to recover from the metastable state. f is a clock sampling frequency, that is, a clock frequency of the register. α is a frequency at which an asynchronous event is triggered, that is, a quantity of asynchronous input changes per second. C1 and C2 are parameters of the register, which are determined by electrical characteristics of the register and can represent a register flip speed. The MTBF can be extended by increasing t or decreasing C1, C2, α, and f, to extend an interval between two failures. Currently, a common practice in the industry for reduction of a probability of a metastable state is to increase a value of t, that is, to increase a beat quantity of an asynchronous sampling register. However, an increase in the beat quantity of the asynchronous sampling register significantly increases a system delay and greatly affects system performance. Therefore, it is significant to improve a metastable state elimination capability of a synchronizer register.

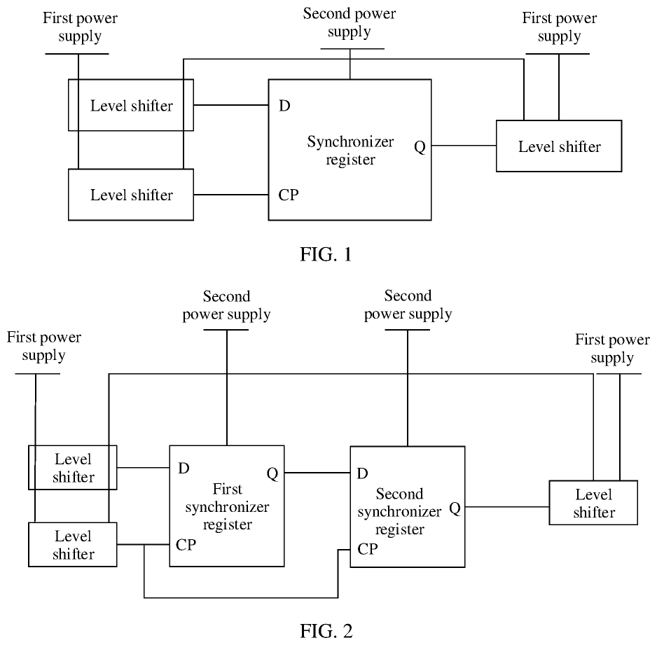

FIG. 1 is a schematic diagram of a structure of a circuit. As shown in FIG. 1, the circuit includes one synchronizer register and N level shifters. The synchronizer register includes N ports, where N is a positive integer. Any one of the N level shifters includes two ports, where one of the two ports is connected to any one of the N ports of the synchronizer register, and the other port is connected to a first power supply. The synchronizer register is powered by a second power supply. In other words, each of the N ports of the synchronizer register is connected to one level shifter, the second power supply supplies power to the synchronizer register, and the level shifter is powered by a dual-rail power supply, that is, the level shifter supports dual-rail power supply. The power supply for the level shifter includes the first power supply and the second power supply. The first power supply supplies power to a peripheral logic circuit, and the peripheral logic circuit is a circuit other than the foregoing circuit in a device including the foregoing circuit. The second power supply supplies power to the synchronizer register. A higher voltage indicates a smaller value of C1. Therefore, in an implementation, the second power supply has a high voltage, and the first power supply has a low voltage. In the embodiments and accompanying drawings, the terms “first”, “second”, and the like are intended to distinguish between similar objects but do not represent a limitation on the solutions.

It should be noted that a quantity of ports included in the synchronizer register is not limited in the embodiments. As shown in FIG. 1, the synchronizer register includes three ports: an input port D, an output port Q, and a clock port CP. The three ports are merely examples for description, and this does not represent a limitation on the quantity of the ports included in the synchronizer register.

It can be understood, from the structure of the circuit shown in FIG. 1, that the synchronizer register is powered by a separate power supply, which is different from the power supply for the peripheral logic circuit. That a synchronizer register and a peripheral logic circuit are powered by a same power supply may have the following disadvantages: For example, a voltage may be reduced for power consumption reduction. However, reducing the voltage increases a value of C1 of the synchronizer register. According to the foregoing description, an increase in the value of C1 weakens the metastable state elimination capability of the synchronizer register. In addition, for another example, a quantity of phase inverters on a feedback path in the synchronizer register may usually be increased to improve the metastable state elimination capability of the synchronizer register. However, when a voltage of the power supply for the synchronizer register and the peripheral logic circuit is determined, only an increase in a quantity of phase inverters on the feedback path of the synchronizer register gradually decreases the impact on improvement of the metastable state elimination capability of the synchronizer register. The disadvantage that may exist when a synchronizer register and a peripheral logic circuit are powered by the same power supply can be resolved by using the circuit structure shown in FIG. 1. A supply voltage of the synchronizer register can be increased separately, that is, a voltage of the second power supply can be increased by using the circuit structure shown in FIG. 1. Compared with a solution in which the synchronizer register and the peripheral logic circuit are powered by the same power supply, this solution may further improve the metastable state elimination capability of the synchronizer register. In addition, when a voltage of the power supply for the peripheral logic circuit decreases, that is, when a voltage of the first power supply mentioned above decreases, the power supply voltage of the synchronizer register may remain unchanged, that is, the voltage of the second power supply remains unchanged, so that the metastable state elimination capability of the synchronizer register is not affected.

The circuit shown in FIG. 1 includes only one synchronizer register. In an implementation, the circuit may include a plurality of synchronizer registers.

FIG. 2 is a schematic diagram of a structure of another circuit. A quantity of synchronizer registers in the circuit may be increased to further reduce a probability of a metastable state. A quantity of synchronizer registers that may be included in the circuit is not limited in this embodiment. As shown in FIG. 2, an example in which the circuit includes two synchronizer registers is used for description. The two synchronizer registers are connected in a cascading manner. Cascading means that an output of one synchronizer register is used as an input for the other synchronizer register. As shown in FIG. 2, a first synchronizer register and a second synchronizer register are connected in a cascading manner, and each of other ports of the first synchronizer and the second synchronizer is connected to one level shifter. The other ports herein are ports of the synchronizer register other than a port for cascading connection. Each level shifter in the circuit supports dual-rail power supply. Cascaded synchronizer registers are powered by a same power supply. A power supply for a peripheral logic circuit is different from the power supply for the synchronizer register. Peripheral logic circuits are powered by a same power supply.

An electronic device may include the circuit described above. In an implementation, the electronic device may further include a dual-rail memory. A dual-rail memory is a current type memory. When a device includes both a dual-rail memory and a synchronizer register, a dual-rail power supply supported by a level shifter is the dual-rail power supply for the dual-rail memory. A high-voltage power supply in the dual-rail memory may supply power to the synchronizer register. When a voltage of the high-voltage power supply is increased, the metastable state elimination capability of the synchronizer register can be improved.

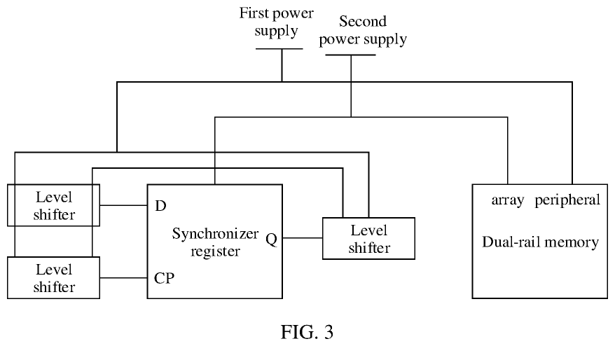

As shown in FIG. 3, an example in which a circuit includes one synchronizer register is used for description. If a power supply for a memory cell array is a high-voltage power supply in a dual-rail memory, and a power supply for a peripheral circuit of the memory is a low-voltage power supply in the dual-rail memory, the power supply for the array supplies power to the synchronizer register, and the power supply for the peripheral supplies power to a peripheral logic circuit. The peripheral logic circuit herein is a circuit in the electronic device other than the synchronizer register and the dual-rail memory. In addition to supplying power to the synchronizer register by using the high-voltage power supply in the dual-rail memory listed in this implementation, there are other manners. For example, a high-voltage power supply may be needed to supply power to the synchronizer register. Alternatively, the power supply is connected to a high-voltage power supply for the synchronizer register, to improve the metastable state elimination capability of the synchronizer register.

The circuit and the electronic device provided in the embodiments are described in detail above. The principles and implementations are described herein by using examples. The description about the foregoing embodiments is merely provided to help understand the methods and the core ideas. In addition, a person of ordinary skill in the art can make modifications to the implementations. In conclusion, the content of the embodiments shall not be construed as a limitation.

1. A circuit, comprising:
a synchronizer register; and
a level shifter, wherein the synchronizer register is electrically connected to the level shifter, the level shifter is powered by a dual-rail power supply, and a high-voltage power supply in the dual-rail power supply supplies power to the synchronizer register.

2. The circuit according to claim 1, wherein the circuit comprises:
one synchronizer register; and
N level shifters, the synchronizer register comprises N ports, each of the N ports is connected to one of the N level shifters, and level shifters connected to any two of the N ports are different, wherein N is a positive integer.

3. The circuit according to claim 1, wherein the circuit comprises:
M synchronizer registers, the M synchronizer registers are connected in a cascading manner, and the high-voltage power supply in the dual-rail power supply supplies power to the M synchronizer registers, wherein M is a positive integer.

4. The circuit according to claim 3, wherein M is 2.

5. An electronic device, wherein the electronic device comprises a circuit, the circuit comprises:
a synchronizer register; and
a level shifter, the synchronizer register is electrically connected to the level shifter, the level shifter is powered by a dual-rail power supply, and a high-voltage power supply in the dual-rail power supply supplies power to the synchronizer register.

6. The electronic device according to claim 5, wherein the circuit comprises:
one synchronizer register and
N level shifters, the synchronizer register comprises N ports, each of the N ports is connected to one of the N level shifters, and level shifters connected to any two of the N ports are different, wherein N is a positive integer.

7. The electronic device according to claim 5, wherein the circuit comprises:
M synchronizer registers, the M synchronizer registers are connected in a cascading manner, and the high-voltage power supply in the dual-rail power supply supplies power to the M synchronizer registers, wherein M is a positive integer.

8. The electronic device according to claim 7, wherein M is 2.

9. The electronic device according to claim 5, further comprising:
a peripheral logic circuit, wherein a low voltage in the dual-rail power supply supplies power to the peripheral logic circuit.

10. The electronic device according to claim 5, further comprising:
a dual-rail memory, wherein the dual-rail power supply for the level shifter is the dual-rail power supply for the memory.
